(19) United States
(12) Patent Application Publication
(10) Pub. No.: US 2015/0156877 A1
(43) Pub. Date: Jun. 4, 2015

(54) STRIP LEVEL SUBSTRATE INCLUDING WARPAGE PREVENTING MEMBER AND METHOD OF MANUFACTURING THE SAME

(71) Applicant: SAMSUNG ELECTRO-MECHANICS CO., LTD., Suwon-si (KR)

(72) Inventors: Ho Shik KANG, Chungcheongnam-do (KR); Jong Tae PARK, Chungcheongnam-do (KR); Sang Il EUN, Chungcheongnam-do (KR)

(73) Assignee: SAMSUNG ELECTRO-MECHANICS CO., LTD., Suwon-si (KR)

(21) Appl. No.: 14/253,550

(22) Filed: Apr. 15, 2014

(30) Foreign Application Priority Data
Nov. 29, 2013 (KR) 10-2013-0147341

(51) Int. Cl. H05K 1/11; H05K 3/10; H05K 1/09

(52) U.S. Cl. CPC H05K 1/119; H05K 1/09; H05K 1/115; H05K 3/103; H05K 2201/09009; H05K 2201/032; H05K 2201/0137

(57) ABSTRACT

Disclosed herein is a strip level substrate having a plurality of unit level substrate regions partitioned by unit saw lines, including: a plurality of wiring layers and a plurality of insulating layers that are alternately stacked; and warpage preventing members disposed in unit saw line regions of an insulating layer bonded to a carrier member among the plurality of insulating layers, in order to improve warpage characteristics of the strip level substrate.

### CROSS REFERENCE(S) TO RELATED APPLICATIONS

This application claims the foreign priority benefit under 35 U.S.C. Section 119 of Korean Patent Application Serial No. 10-2013-0147341, entitled “Strip Level Substrate Including Warpage Preventing Member and Method of Manufacturing the Same” filed on Nov. 29, 2013, which is hereby incorporated by reference in its entirety into this application.

### BACKGROUND OF THE INVENTION

1. Technical Field

The present invention relates to a strip level substrate, and more specifically, to a strip level substrate having improved warpage characteristics.

2. Description of the Related Art

Generally, a printed circuit board (PCB) is a product in which wirings are formed using a copper foil on one surface or both surfaces of a board made of various thermosetting synthetic resins, semiconductor chips, and the like, are disposed on and fixed to the board, and electrical wirings are implemented between the semiconductor chips and the board. In accordance with a trend toward miniaturization, densification, thinness, and the like, of electronic components, research into thinness and multi-functionalization of the printed circuit board has been actively conducted.

Recently, in order to increase a production amount per unit time and wiring density, a coreless manufacturing process using a carrier member has been used. That is, substrates including a plurality of wiring layers are formed on both surfaces of the carrier member by a build-up process and are finally separated from the carrier member (Korean Patent Laid-Open Publication No. 10-2013-0001015).

In this case, in a process of forming a plurality of circuit layers, deformation of the substrate such as warpage may be caused. The warpage of the substrate as described above leads to a bonding defect between a semiconductor chip and the substrate, or the like, which makes the subsequent process difficult to deteriorate reliability and productivity of a product.

### RELATED ART DOCUMENT

### Patent Document

(Patent Document 1) Korean Patent Laid-Open Publication No. 10-2013-0001015

### SUMMARY OF THE INVENTION

An object of the present invention is to provide a strip level substrate capable of preventing warpage that may occur at the time of performing a coreless method by including a warpage preventing member.

According to an exemplary embodiment of the present invention, there is provided a strip level substrate having a plurality of unit level substrate regions partitioned by unit saw lines, including: a plurality of wiring layers and a plurality of insulating layers that are alternately stacked; and warpage preventing members disposed in unit saw line regions of an insulating layer bonded to a carrier member among the plurality of insulating layers.

The warpage preventing member may be buried in a surface bonded to the carrier member.

The warpage preventing member may be made of at least one selected from a group consisting of copper (Cu), silver (Ag), aluminum (Al), palladium (Pd), nickel (Ni), titanium (Ti), gold (Au), iron (Fe), tungsten (W), molybdenum (Mo), aluminum (Al), invar, and kovar.

The warpage preventing member may be made of the same metal material as that of the wiring layer.

The warpage preventing member may have the same thickness as that of the lowermost wiring layer.

The warpage preventing member may be disposed so as to cover the entirety of the unit saw line region.

The warpage preventing member may have a width smaller than that of the unit saw line region.

According to another aspect of the present invention, there is provide a method of manufacturing a strip level substrate, including: preparing a strip level carrier member having a plurality of unit level substrate regions partitioned by unit saw lines; forming warpage preventing members in unit saw line regions of the carrier member; forming strip level substrates on both surfaces of the carrier member; and separating the strip level substrates from the carrier member.

In the forming of the strip level substrates, a step of forming a wiring layer in the unit level substrate region and a step of stacking an insulating layer so as to cover an entire region including the unit level substrate region and the unit saw line region may be repeatedly performed.

In the forming of the wiring layer, the wiring layer bonded to the carrier member may be formed together with the warpage preventing members in the forming of the warpage preventing members.

The method may further include, after the separating of the strip level substrates, stacking build-up layers on upper and lower portions of the strip level substrates.

The carrier member may have a structure in which first and second metal plates are stacked on upper and lower portions of a core insulating layer with each of release layers disposed therebetween, and in the separating of the strip level substrates, the release layers may be removed.

The method may further include, after the separating of the strip level substrates, etching the first metal plates bonded to outer layers of the strip level substrates.

### BRIEF DESCRIPTION OF THE DRAWINGS

FIG. 1 is a plan view of a strip level substrate according to an exemplary embodiment of the present invention;

FIG. 2 is a cross-sectional view taken along line I-I′ of FIG. 1;

FIG. 3 is an enlarged view of a unit level substrate region according to an exemplary embodiment of the present invention;

FIG. 4 is a bottom view showing a lower surface of the strip level substrate according to an exemplary embodiment of the present invention;

FIG. 5 is a view showing a modified example of a warpage preventing member according to an exemplary embodiment of the present invention;

FIGS. 6 to 11 are views sequentially showing processes of a method of manufacturing a strip level substrate according to an exemplary embodiment of the present invention; and

FIG. 12 is a view for describing a warpage state in a strip level substrate according to the related art that does not include a warpage preventing member.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Meanwhile, terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

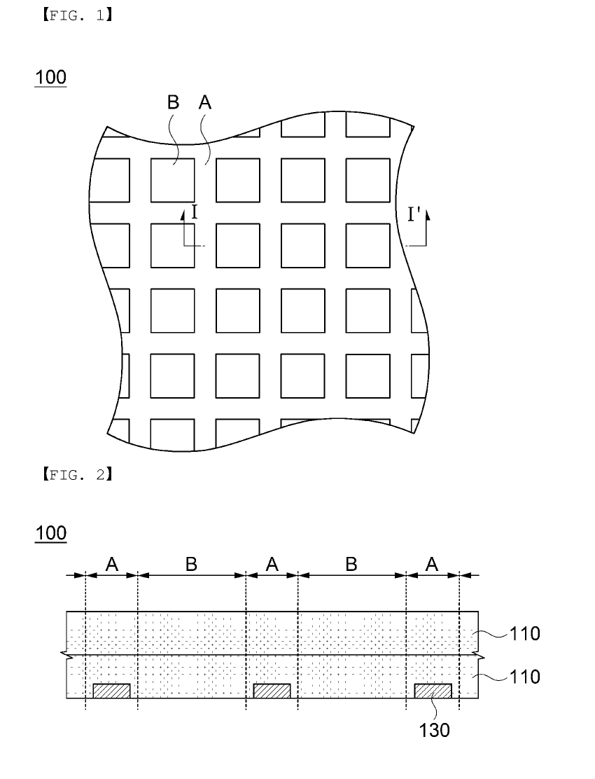

FIG. 1 is a plan view of a strip level substrate according to an exemplary embodiment of the present invention; and FIG. 2 is a cross-sectional view taken along line I-I′ of FIG. 1. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Referring to FIGS. 1 and 2, a strip level substrate 100 according to an exemplary embodiment of the present invention having a plurality of unit level substrate regions B partitioned by unit saw lines A may be a substrate having a multilayer structure in which wiring layers and insulating layers 110 are alternately stacked.

A resin material configuring the insulating layer 110 may be appropriately selected in consideration of an insulating property, heat resistance, moisture resistance, and the like. For example, as an optimal polymer material configuring the insulating layer 110, an epoxy resin, a phenol resin, a urethane resin, a silicon resin, a polyimide resin, or prepreg in which a reinforcing material such as a glass fiber or an inorganic filter is impregnated in these polymer resins may be used.

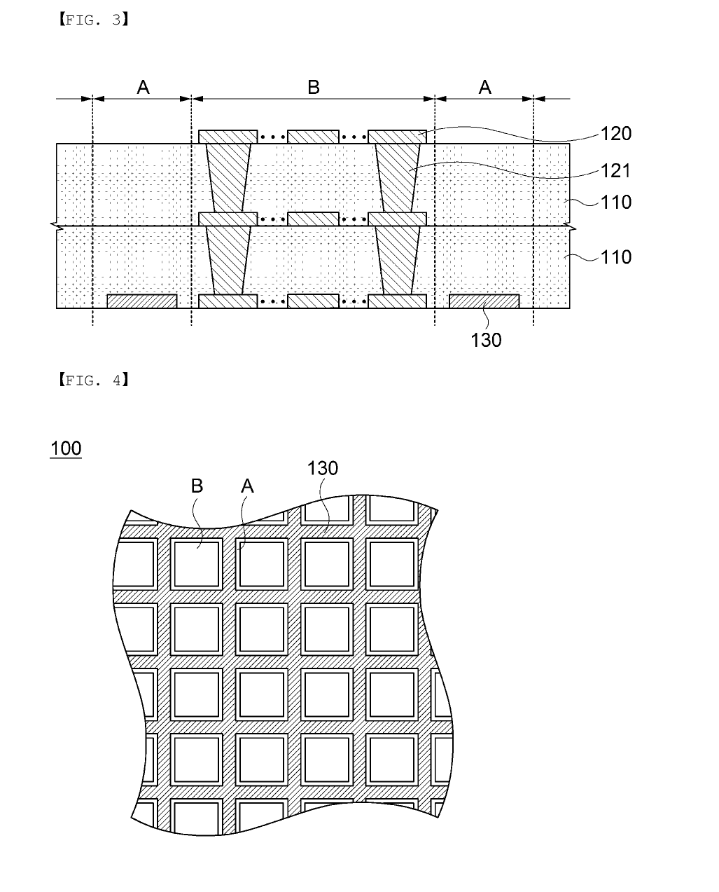

The unit level substrate regions B are regions in which a plurality of semiconductor chips and wiring layers for electrical connection to these semiconductor chips are provided and may be partitioned later and be operated as one substrate. That is, although the unit level substrate region B has been simply shown as a layer in FIG. 2 in order to clearly show only main features of the present invention, referring to FIG. 3, which is an enlarged view of one unit level substrate region B, the unit level substrate region B may include various wiring layers 120 such as a ground wiring forming a ground region, a power supply wiring becoming a power supply unit, and a signal wiring serving as an electrical path, and the like, vias 121 for interconnecting these wiring layers 120, and the like, according to the use thereof. Although the wiring layer 120 having a three-layer structure has been shown by way of example in FIG. 3, the wiring layer 120 may include two or three or more layers if necessary.

The unit level substrate regions B may be arranged in a matrix shape by horizontal and vertical unit saw lines A and may be partitioned later by a blade moving along the unit saw lines A in a sawing process.

As described above, the unit saw lines A, which serve to predefine division positions of the unit level substrate regions B and induce movement of the blade in the sawing process, may have a width at which the blade may pass therethrough. Therefore, hereinafter, a term ‘unit saw line A region’ indicates a region formed by the unit saw line A having a predetermined width.

The strip level substrate 100 according to an exemplary embodiment of the present invention having the above-mentioned structure may be characterized in that warpage preventing members 130 are disposed in the unit saw line A regions.

FIG. 4 is a bottom view showing a lower surface of the strip level substrate according to an exemplary embodiment of the present invention. The warpage preventing members 130 may be disposed in the unit saw line A regions of an insulating layer 110 bonded to a carrier member, that is, the lowermost insulating layer 110, in a process of manufacturing the insulating layer 110 having a multilayer structure.

More specifically, the warpage preventing members 130 may be disposed in a form in which they are buried in a surface bonded to the carrier member, that is, an external exposed surface of the lowermost insulating layer 110. This disposition of the warpage preventing members 130 depends on a direction of warpage of the substrate that may occur at the time of manufacturing the substrate in a coreless scheme. This will be described in detail in a method of manufacturing a strip level substrate according to an exemplary embodiment of the present invention to be described below.

The warpage preventing member 130 may be made of at least one selected from a group consisting of copper (Cu), silver (Ag), aluminum (Al), palladium (Pd), nickel (Ni), titanium (Ti), gold (Au), iron (Fe), tungsten (W), molybdenum (Mo), aluminum (Al), invar, and kovar appropriate for improving warpage preventing performance due to a low coefficient of thermal expansion (CTE).

Since these metal materials generally have a high modulus of about 140 to 150 GPa, they may increase mechanical strength of the substrate. Therefore, in the case of using the strip level substrate 100 according to an exemplary embodiment of the present invention, the warpage preventing performance may be improved and driving efficiency may be secured at the time of performing a process.

It is preferable that the warpage preventing member 130 is made of the same metal material as that of the wiring layer 120 among the above-mentioned metal materials. This is to simultaneously form the lowermost wiring layer 120 and the warpage preventing member 130 for convenience of manufacture. Therefore, thicknesses of the warpage preventing member 120 and the lowermost wiring layer 120 as well as materials of the warpage preventing member 120 and the lowermost wiring layer 120 may be the same as each other.

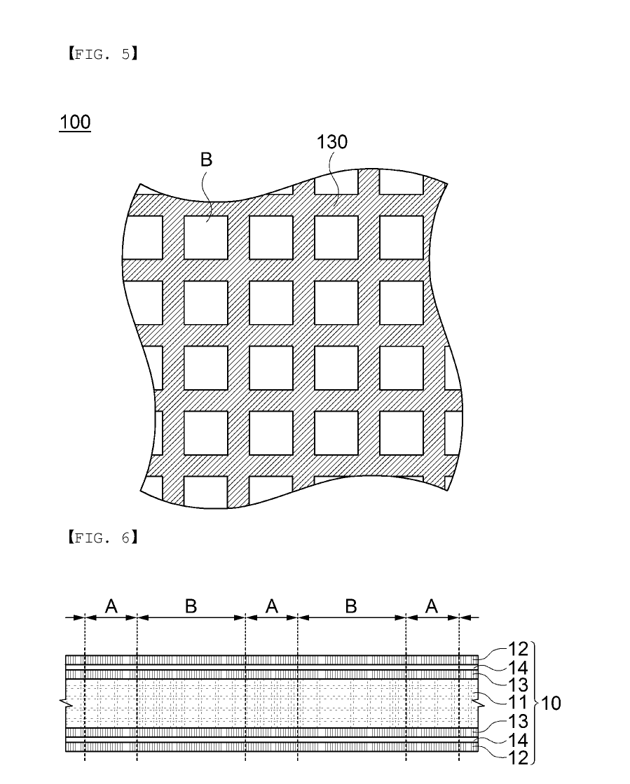

Meanwhile, although the case in which the warpage preventing member 130 has a width smaller than that of the unit saw line A has been shown in FIG. 4, the warpage preventing member 130 may also be disposed so as to cover the entirety of the unit saw line A region, as shown in FIG. 5.

In the case which the warpage preventing member 130 is disposed over the entirety of the unit saw line A region, an area of the warpage preventing member 130 is increased, thereby making it possible to further improve warpage preventing characteristics. Meanwhile, in the sawing process, a blade having a thickness smaller than the width of the unit saw line A is used in consideration of a margin part. However, the warpage preventing member 130 is disposed over the entirety of the unit saw line A region, a portion of the warpage preventing member 130 may remain at edges of unit level substrates partitioned after the sawing process.

Therefore, in the case in which prevention of a defect due to foreign materials is prioritized, the warpage preventing member 130 has a form as shown in FIG. 4, such that it may be completely removed at the edges of the unit level substrates by movement of the blade.

Hereinafter, a method of manufacturing a strip level substrate 100 according to an exemplary embodiment of the present invention will be described.

FIGS. 6 to 11 are views sequentially showing processes of a method of manufacturing a strip level substrate 100 according to an exemplary embodiment of the present invention. First, as shown in FIG. 6, a strip level carrier member 10 is prepared.

The carrier member 10 has a structure in which first and second metal plates 12 and 13 are stacked on upper and lower portions of a core insulating layer 11 with each of release layers 14 disposed therebetween and may be divided into unit saw lines A and a plurality of unit level substrate regions B partitioned by the unit saw lines, which correspond to the strip level substrate 100 according to an exemplary embodiment of the present invention.

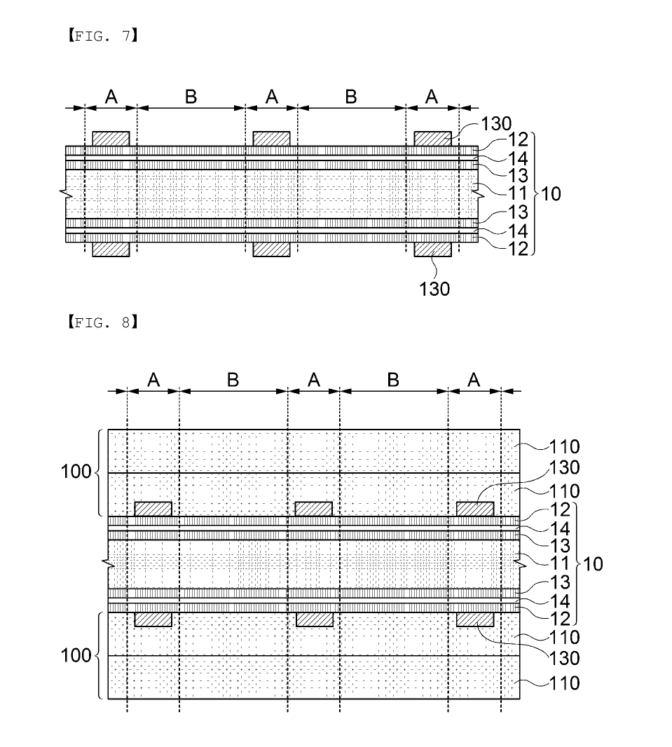

Then, as shown in FIG. 7, the warpage preventing members 130 are formed in the unit saw line A regions of the carrier member 10. The warpage preventing member 130 may be made of a metal material having a low coefficient of thermal expansion and may be formed so as to cover the entirety of the unit saw line A region or be formed at a width smaller than that of the unit saw line A.

Next, as shown in FIG. 8, the strip level substrates 100 are formed on both surface of the carrier member 10. To this end, first, the wiring layer 120 is formed in the unit level substrate region B by a general plating process well-known in the art, for example, a semi-additive process (SAP), a modified semi-additive process (MSAP), a subtractive process, or the like, and the insulating layer 110 is stacked so as to cover an entire region including the unit level substrate region B and the unit saw line A region. In addition, this process may be repeated depending on the number of required layers to form the strip level substrate 100.

Here, the wiring layer 120 bonded to the carrier member 10, that is, the lowermost wiring layer 120 may be formed together with the warpage preventing member 130. Therefore, an additional plating process may be omitted. In this case, the warpage preventing member 130 and the wiring layer 120 may be made of the same metal and may have the same thickness.

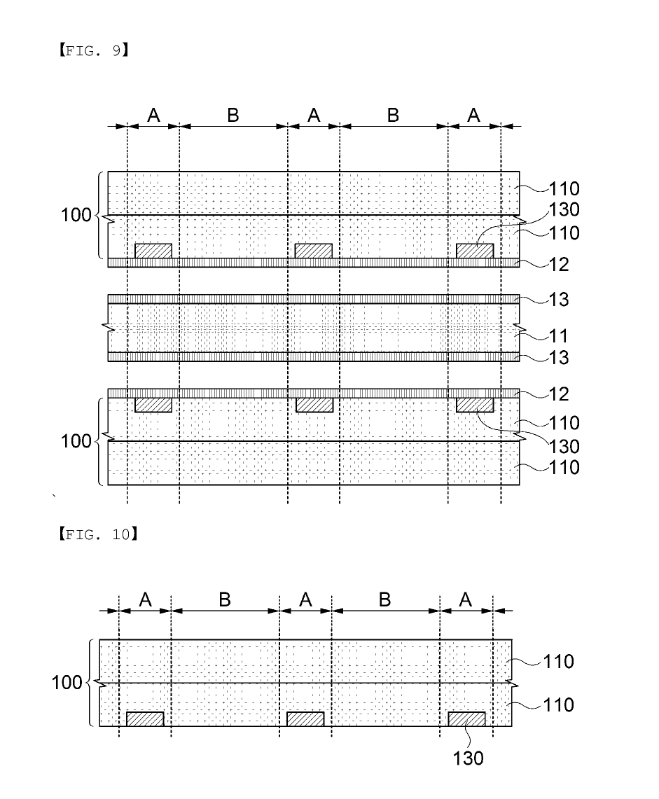

When the strip level substrates 100 are completed as described above, they are separated from the carrier member 10, as shown in FIG. 9.

Since the strip level substrates 100 have a structure in which upper and lower portions thereof are symmetrical to each other based on the carrier member 10 before the strip level substrates 100 are separated from the carrier member 10, warpage of the strip level substrates 100 does not substantially occur. However, the strip level substrates 100 separated from the carrier member 10 have a structure in which upper and lower portions thereof are asymmetrical to each other, warpage may occur in the strip level substrates 100 at the same time of separating the strip level substrates 100 from the carrier member 10.

FIG. 12 is a view for describing a warpage state in a strip level substrate according to the related art that does not include a warpage preventing member. At the time of forming the strip level substrate, a polishing process for planarizing a surface is performed on a stacked insulating layer. When the insulating layer is stacked, stress due to the polishing process is accumulated toward a carrier member 1. As a result, when the strip level substrates 2 are separated from the carrier member 1, warpage occurs in a smile form in the strip level substrate 2 over the carrier member 1 and warpage occurs in a cry form in the strip level substrate 2 under the carrier member 1.

However, when the warpage preventing members 130 made of a metal material are provided in the insulating layer 110 bonded to the carrier member 10, that is, at a lower portion of the strip level substrate, as in the present invention, warpage is induced toward the carrier member 10, that is, in an opposite direction to the warpage direction shown in FIG. 12, due to low thermal expansion of the metal material, thereby making it possible to suppress occurrence of the warpage.

Meanwhile, as described above, since the carrier member 10 is separated by separation of the release layer 14, the first metal plate is bonded to an outer layer of the strip level substrate 100. Therefore, after the strip level substrate 100 is separated from the carrier member 10, the first metal plate 12 on the outer layer of the strip level substrate 100 may be etched, as shown in FIG. 10. In the case of etching the first metal plate 12 made of a metal material, in the strip level substrate according to the related art that does not include a warpage preventing member, warpage may be further intensified in a direction shown in FIG. 12. However, in the strip level substrate 100 according to an exemplary embodiment of the present invention, even though the first metal plate 12 is etched, the warpage preventing member 130 may be still present to suppress generation of the warpage.

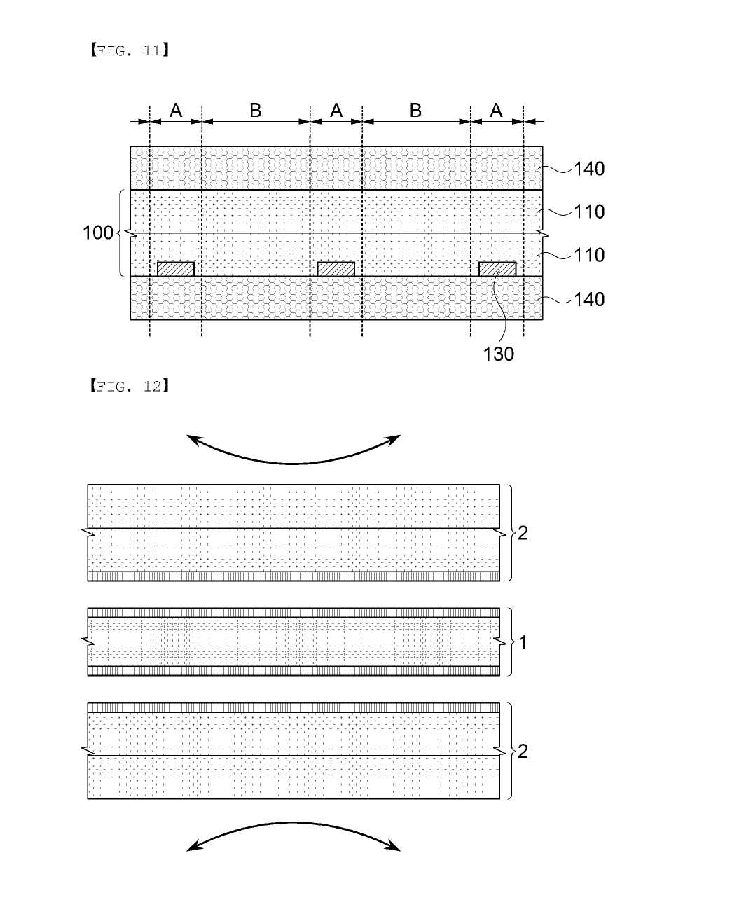

After the first metal plate 12 is etched, a build-up layer 140 including an insulating layer and a wiring layer is additionally stacked, thereby making it possible to increase the number of wiring layers, as shown in FIG. 11. Then, the sawing process is performed along the unit saw lines A of the strip level substrates 100, thereby making it possible to partition the unit level substrate region B.

According to an exemplary embodiment of the present invention, the warpage preventing members made of a metal material are disposed in the lowermost insulating layer bonded to the carrier member in the strip level substrate, thereby making it possible to prevent warpage of the substrate that may occur when the substrate is separated from the carrier member. In addition, mechanical strength of the substrate is increased, thereby making it possible to secure driving efficiency at the time of performing a process.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed exemplary embodiments. It is to be understood that other exemplary embodiments are also included within the spirit and scope of the appended claims.

What is claimed is:

1. A strip level substrate having a plurality of unit level substrate regions partitioned by unit saw lines, comprising:
a plurality of wiring layers and a plurality of insulating layers that are alternately stacked; and
warpage preventing members disposed in unit saw line regions of an insulating layer bonded to a carrier member among the plurality of insulating layers.

2. The strip level substrate according to claim 1, wherein the warpage preventing member is buried in a surface bonded to the carrier member.

3. The strip level substrate according to claim 1, wherein the warpage preventing member is made of at least one selected from a group consisting of copper (Cu), silver (Ag), aluminum (Al), palladium (Pd), nickel (Ni), titanium (Ti), gold (Au), iron (Fe), tungsten (W), molybdenum (Mo), aluminum (Al), invar, and kovar.

4. The strip level substrate according to claim 1, wherein the warpage preventing member is made of the same metal material as that of the wiring layer.

5. The strip level substrate according to claim 1, wherein the warpage preventing member has the same thickness as that of the lowermost wiring layer.

6. The strip level substrate according to claim 1, wherein the warpage preventing member is disposed so as to cover the entirety of the unit saw line region.

7. The strip level substrate according to claim 1, wherein the warpage preventing member has a width smaller than that of the unit saw line region.

8. A method of manufacturing a strip level substrate, comprising:
preparing a strip level carrier member having a plurality of unit level substrate regions partitioned by unit saw lines;
forming warpage preventing members in unit saw line regions of the carrier member;
forming strip level substrates on both surfaces of the carrier member; and
separating the strip level substrates from the carrier member.

9. The method according to claim 8, wherein in the forming of the strip level substrates, a step of forming a wiring layer in the unit level substrate region and a step of stacking an insulating layer so as to cover an entire region including the unit level substrate region and the unit saw line region are repeatedly performed.

10. The method according to claim 9, wherein in the forming of the wiring layer, the wiring layer bonded to the carrier member is formed together with the warpage preventing members in the forming of the warpage preventing members.

11. The method according to claim 8, further comprising, after the separating of the strip level substrates, stacking build-up layers on upper and lower portions of the strip level substrates.

12. The method according to claim 8, wherein the carrier member has a structure in which first and second metal plates are stacked on upper and lower portions of a core insulating layer with each of release layers disposed therebetween, and
in the separating of the strip level substrates, the release layers are removed.

13. The method according to claim 12, further comprising, after the separating of the strip level substrates, etching the first metal plates bonded to outer layers of the strip level substrates.
